(19) United States
(12) Patent Application Publication
(10) Pub. No.: US 2020/0191874 A1
(43) Pub. Date: Jun. 18, 2020

(54) Method for Determining the State of an Electrical Line Linking a Battery Cell to a Monitoring Unit, and Corresponding Monitoring Unit

(71) Applicant: Nissan Motor Co., Ltd., Yokohama-shi, Kanagawa (JP)

(72) Inventor: Julien Malrieu, Guyancourt (FR)

(21) Appl. No.: 16/643,369

(22) PCT Filed: Jul. 9, 2018
(86) PCT No.: PCT/EP2018/068565

§ 371 Date: Feb. 28, 2020

(30) Foreign Application Priority Data
Sep. 4, 2017 (FR) 1758138

(51) Int. Cl. G01R 31/3835; G01R 31/396; G01R 31/58; G01R 31/66

(52) U.S. Cl. CPC G01R 31/3835; G01R 31/66; G01R 31/58; G01R 31/396

(57) ABSTRACT

A method for determining the state of an electrical line connecting a cell of a battery to a monitoring unit of said battery, said electrical line including a first electrical branch connecting a positive terminal of said cell to a first input terminal of said monitoring unit and a second electrical branch connecting a negative terminal of said cell to a second input terminal of said monitoring unit, said method includes:
calculating a value of the line resistance of said electrical line; and
determining the state of said electrical line as a function of said calculated line resistance value.

### CROSS-REFERENCE TO RELATED APPLICATION

This application claims priority to and the benefit of French Application Patent Serial No. 1758138, filed Sep. 4, 2017, the entire disclosure of which is hereby incorporated by reference.

### TECHNICAL FIELD

The present invention is generally concerned with the field of batteries. It more particularly concerns the field of the electrical management of the cells of a battery. It concerns in particular a method for determining the state of an electrical line connecting a cell of a battery to a unit for monitoring said battery. It also concerns a method for issuing an alert regarding the state of said line. It finally concerns a unit for monitoring the states of charge of the cells of a battery and a system for motor vehicles including such a unit.

### BACKGROUND

Monitoring the states of charge (SoC) of the electrochemical cells of a battery, for example of lithium-ion (Li-Ion) batteries, becomes necessary in order to be able to cause said battery to function in its safe range, in particular to prevent overvoltages or undervoltages at the terminals of the electrical cells. To this end, the electrical voltage between the positive and negative terminals of each cell must be monitored regularly, whether the battery is charging or discharging, or at rest (battery more or less charged but not delivering any current). Measuring the voltage at the terminals of said cells is subject to strong safety constraints (surveillance of overvoltages or undervoltages) and performance constraints (accuracy of measurement of the state of charge). The cells of the battery are generally monitored by means of an electronic unit that is connected to each cell by an electrical line, each electrical line including two electrical branches connecting the two terminals of each cell to two input terminals of the electronic unit. In particular there are known so-called balancing electronic units (BMS (battery management systems)) that enable optimum operation of a battery by equalizing the states of charge of all of the electrical cells of a battery, whether the battery is operating (charging or discharging) or not.

When the electrical lines are long (e.g. when the monitoring unit is installed far from the battery) or the state of those lines (i.e. of their electrical branches) may deteriorate, it is necessary to determine the line resistance of each electrical line. By line “resistance” is meant the real part of the impedance of the electrical line, that impedance being a complex number in the mathematical sense of the term (i.e. having a real part and an imaginary part). The value of the line resistance is measured in ohms.

For example, mere deterioration of contact in the wiring between one of the electrical branches and one of the terminals of the cell may seriously impact (increase) the resistance of the line with the result that the voltage measurements effected by the monitoring unit are falsified. Consequently, if the electrical line is faulty and for example has too high a line resistance, controlling the balancing of the cells can lead to non-optimum operation of the battery, for example reduction of its autonomy. Moreover, if the voltage measurements effected by the monitoring unit are falsified, then the onboard diagnostic functions may also be falsified, bringing about feeding of false diagnoses to the electronic unit. In the case of active cell balancing, this could for example lead to poor balancing voltage compensation.

### SUMMARY

In order to remedy the aforementioned disadvantage of the prior art, the present invention proposes a method for determining the state of an electrical line making it possible to detect whether one of the electrical lines is faulty or not.

There is more particularly proposed in accordance with the invention a method for determining the state of an electrical line connecting a cell of a battery to a monitoring unit of said battery, said electrical line including a first electrical branch connecting a positive terminal of said cell to a first input terminal of said monitoring unit and a second electrical branch connecting a negative terminal of said cell to a second input terminal of said monitoring unit, said method including:
a step of calculating a value of the line resistance of said electrical line; and
a step of determining the state of said electrical line as a function of said calculated line resistance value.

Accordingly, by determining in each cycle of use of the battery the state of the electrical line, it is possible to detect if an electrical line (i.e. a cell) is faulty and must be disconnected to maintain safe and efficient operation of the battery and to deactivate the onboard diagnostic functions that could be impacted. In the sense of the invention, it is understood that the line resistance is the sum of the resistances (i.e. of the real parts of the impedances) of the first electrical branch and of the second electrical branch that form said electrical line.

Advantageously, said step of calculating the line resistance value includes:
a first substep of measuring at a first measurement time when said battery cell is not charging or discharging a first open circuit voltage value between said first and second input terminals;
a closing substep at a first time during which the monitoring unit connects said first and second input terminals via a resistance electrical branch the electrical resistance value of which is predetermined;
a second substep of measuring at a second measurement time separated from said first measurement time by a duration between a predetermined minimum duration and a predetermined maximum duration a closed circuit second voltage value between said first and second input terminals; and
a substep of estimating said line resistance value of said electrical line as a function of said predetermined electrical resistance value and said first and second measured voltage values. Accordingly, thanks to the monitoring unit that is able to open and to close the electrical circuit between the two input terminals associated with a particular cell, it is possible to effect two voltage measurements at these input terminals in an open circuit and in a closed circuit on a known resistance so that it is possible to deduce from this the value of the line resistance of that electrical line and to determine the state of the latter.

During the closing substep (B2), each resistive electrical branch is preferably an electrical branch for balancing a cell.

More preferably, said minimum duration is predetermined so that said second measurement substep is carried out under static electrical conditions.

By static electrical conditions is meant the electrical conditions that are established after transitory conditions caused by sudden voltage or current variations. In order to execute the second substep under static electrical conditions, there may be envisaged executing the closed circuit voltage measurement at the input terminals of the monitoring unit using a voltage measuring device having an input low-pass filter, for example a simple first order divider circuit with a resistor (of value R in ohms) and a capacitor (of capacitance C in farads), termed an “RC filter”, the cut-off frequency of which (in hertz or s⁻¹), denoted f_{c}, is equal to 1/(2*π*R*C).

In other words, it will be considered that the second substep is executed under static electrical conditions if the interval between the first measurement time and the second measurement time is greater than five times 2*π*R*C, i.e. 10*π*R*C. In practise, this interval is of the order of a few milliseconds (ms), for example between 1 and 100 ms inclusive, preferably less than 10 ms.

Said maximum duration is also preferably predetermined so that the absolute value of the voltage between said positive and negative terminals of said cell does not vary more than 1% between the first measurement substep and the second measurement substep. In other words, the closed circuit voltage measurement is carried out sufficiently early for it to be possible to ignore the variation of the electrical load between the first and second measurement substeps. In this way, the electrical voltage between the positive and negative terminals of the cell concerned remains virtually constant (to within 1% maximum) between the two measurements.

In one particular embodiment, the determination method includes a step of comparing the calculated line resistance value with an electrical resistance threshold value and, in the determination step, the state of said electrical line is determined as a function of the result of said comparison.

In practice, the electrical line connecting said cell to the monitoring unit will be determined as being faulty if the calculated line resistance value is greater than the electrical resistance threshold value, which is therefore a maximum threshold value not to be exceeded.

Conversely, if the calculated line resistance value is less than the electrical resistance threshold value, then that means that said electrical line is correct, in particular that the connections between the cell and the unit are not greatly impacting monitoring the cells of the battery.

The determination method advantageously further includes a step of measuring a temperature representative of the ambient temperature of said electrical line, and said electrical resistance threshold value is predetermined as a function of that representative temperature. This makes it possible to improve the accuracy of the voltage measurements to the degree that, on the one hand, the line resistance looked for and, on the other hand, the internal resistance of the cell concerned vary as a function of the ambient temperature of the electrical line. The variation of an internal resistance of a cell is generally inversely proportional to the temperature variation whereas the line resistance tends rather to increase as the temperature increases.

In practise, the ambient temperature of the electrical line varies in a temperature range in which the internal resistance of each cell is very much lower than the line resistance.

The invention also proposes a method of controlling a battery cell by means of a monitoring unit, an electrical line connecting said battery cell to said monitoring unit of said battery, said electrical line (201, 202, 203, 204, 205, 206) including a first electrical branch connecting a positive terminal of said cell and a first input terminal of said control unit and a second electrical branch connecting a negative terminal of said cell and a second input terminal of said monitoring unit, said control method including:
a step of determining the state of said electrical line using a determination method as mentioned above; and
if the line resistance value of said electrical line is greater than said electrical resistance threshold value, a step of deactivating the diagnostic functions impacted by the change of the line resistance value of said electrical line.

In fact, too high a line resistance value may be the sign of a faulty connection or of deterioration of contact of said electrical line. In this case, when balancing the cell, it is probable that the voltage measurements at the terminals of that cell when the latter is functioning will be falsified, leading to incorrect compensation of measurement errors when balancing the cells or to feeding incorrect built-in diagnostics using a balancing function of the monitoring unit.

This control method can obviously be applied with advantage to a plurality of or to all the cells of the battery.

If a fault is detected on the electrical line connecting a battery cell to the monitoring unit, the choice may equally be made not to “deactivate” the balancing of the cell but merely to advise a user of the battery.

The invention therefore concerns a method of issuing an alert regarding the state of an electrical line connecting a cell of a battery to a monitoring unit of said battery, said electrical line including a first electrical branch connecting a positive terminal of said cell to a first input terminal of said monitoring unit and a second electrical branch connecting a negative terminal of said cell to a second input terminal of said monitoring unit, said method of issuing an alert including:
a step of determining the state of said electrical line using a determination method as described above; and
a step of sending an alert signal if the line resistance value is greater than said electrical resistance threshold value.

The invention moreover proposes a unit for monitoring states of charge of a plurality of cells of a battery, each cell being connected to said monitoring unit by an electrical line including a first electrical branch connecting a positive terminal of said cell to a first input terminal of said monitoring unit and a second electrical branch connecting a negative terminal of said cell to a second input terminal of said monitoring unit, said monitoring unit being designed:
to calculate a line resistance value of each electrical line; and
to determine the state of said electrical lines as a function of said calculated line resistance values.

The monitoring unit of the invention may for example include an application-specific standard product (ASSP) specifically designed:
to open a circuit associated with each of the electrical cells of the battery, by opening the circuit between each first and second input terminal associated with said cell;
to close a circuit associated with each of the same electrical cells so that each first and second input terminal of the unit are connected to one another via a purely resistive electrical branch under static conditions, the resistance of that branch being known and fixed;
to measure open circuit or closed circuit electrical voltage values between each first input terminal and each second input terminal under the conditions just described above; and
as a function of the measured values and prior knowledge of the known resistance, to calculate the line resistance of each electrical line associated with a cell of the battery.

The invention finally proposes a system for electric or hybrid motor vehicles, including:
a battery comprising a plurality of cells; and
a unit as described above for monitoring said battery.

The invention also proposes an electric or hybrid motor vehicle including:
a system as described above; and
an electric motor supplied with current by said battery of said system.

### BRIEF DESCRIPTION OF THE DRAWINGS

The following description with reference to the appended drawings, provided by way of nonlimiting example, clearly explains in what the invention consists and how it may be reduced to practise. In the appended drawings:

FIG. 1 is a diagrammatic view of a battery and a unit for monitoring that battery;

FIG. 2 is an equivalent electrical circuit diagram under static conditions of a cell of the battery from FIG. 1 connected to a printed circuit card of the unit from FIG. 1; and

FIG. 3 is a schematic diagram of a determination method according to the invention.

### DETAILED DESCRIPTION

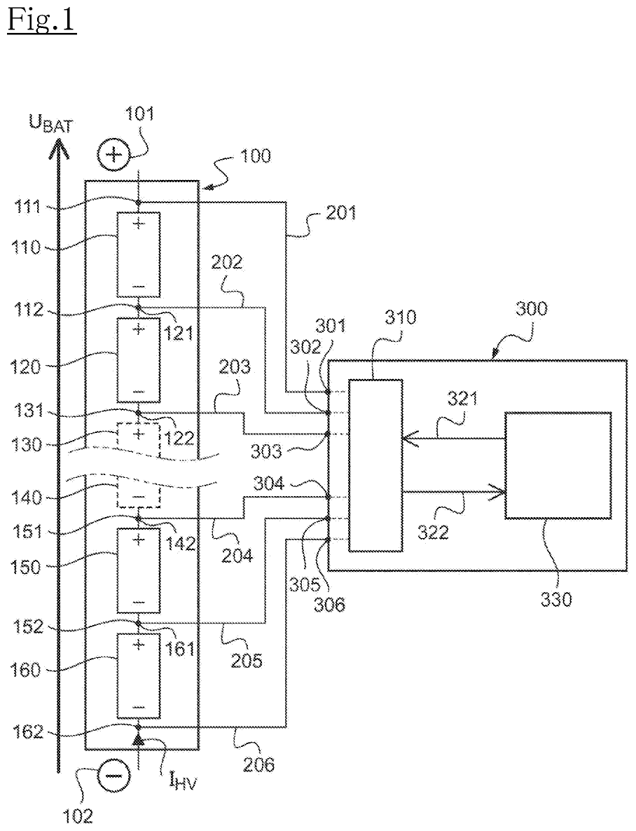

In order to make the description more concrete and easier for the reader to understand, there will be described hereinafter with reference to FIGS. 1 to 3 one particular embodiment of the invention in the automotive field, in particular for the electrical management by a monitoring unit 300 of a battery 100 (see FIG. 1) equipping an electric or hybrid motor vehicle.

However, the methods and products of the invention described hereinafter are in no way limited to this type of application and could equally well be implemented or used with a battery in another technical field (e.g. lighting, electronic power supply, heating or air conditioning, etc.).

The motor vehicle, which has not been shown here, includes:
a system including said battery 100 and said unit 300 for monitoring said battery 100 adapted to monitor and to control the states of charge of a plurality of electrical cells 110, 120, 130, 140, 150, 160 of the battery 100; and
an electric motor designed to propel said motor vehicle when it is supplied with current I_{HV} (see FIG. 1) by the battery 100 of said system, and means for charging the battery 100.

Here these means for charging the battery 100 include a simple electrical charger that is adapted to be connected on one side of the terminals of an electrical socket outlet of a domestic electrical mains supply and on the other side to the positive terminal 101 and the negative terminal 102 of the battery 100. Alternatively, or additionally, the charging means could also include recuperative braking means enabling recovery of energy generated by braking the motor vehicle in order to charge the battery 100.

Here the battery 100 is a “traction” battery intended to supply with current I_{HV} (see FIG. 1) the electric motor and various auxiliary devices connected to the electrical network of the vehicle.

It conventionally includes a storage box (not shown) from which emerge the positive terminal 101 and the negative terminal 102.This storage box houses the plurality of electrical cells 110, 120, 130, 140, 150, 160 the nominal voltages and the number of which are calculated so that the electric motor is able to develop a torque (measured in newton meters or N·m) and/or a power (measured in watts or in horse power) sufficient to propel the motor vehicle for a predetermined time or over a predetermined distance.

100 to 200 cells are typically used that are connected in such a manner that the voltage at the positive terminal 101 and the negative terminal 102 of the battery 100 is of the order of 400 volts (V) and of sufficient capacity. Each cell usually has a nominal voltage at its terminals of the order of 2 to 5V. Here the cells 110, 120, 130, 140, 150, 160 are of lithium-ion (Li-Ion) type and each has a nominal voltage of approximately 3.7V when they are fully charged. Accordingly, in the example from FIG. 1, the battery 100 includes 108 single Li-Ion cells connected in series but to clarify the drawings only six of those cells 110, 120, 130, 140, 150, 160 are represented in the figures:
the first two cells 150, 160: cells of rank No.1 and No.2;
the last two cells 110, 120: cells of rank No.107 and No.108; and
the cells 130, 140: cells of rank No.3 and No.106 (represented in part in dashed line in FIG. 1).

In practise, at the beginning of a cycle of use, the various individual cells 110, 120, 130, 140, 150, 160 of the traction battery 100 do not all have the same state of charge: this is referred to as a “cell balancing problem”. This is because the various cells are not all strictly identical (their capacities and their internal resistances are not exactly equal on leaving the manufacturing plant), and do not evolve in the same way over time, i.e. they are not all discharged in the same manner (self-discharge dispersion). Moreover, the various cells are placed in the box of the battery 100 in zones that are more or less cooled or ventilated, the temperatures around each cell being different. Accordingly, some of the cells of the traction battery are stressed more than others, which reduces the overall capacity of the traction battery and its service life.

As shown in FIG. 1, each cell 110, 120, 130, 140, 150, 160 of the battery 100 includes a positive terminal 111, 121, 131, 151, 161 and a negative terminal 112, 122, 142, 152, 162 (the negative terminal of the cell 130 and the positive terminal of the cell 140 cannot be seen in FIG. 1). The cells 110, 120, 130, 140, 150, 160 of the battery 100 being connected in series, the positive terminal of the cell of rank n (n/=1 . . . N−1, here with N=108), for example the terminal 121 of the cell 120 (of rank No.107) is connected with the negative terminal of the adjacent cell of rank n+1, here the negative terminal 112 of the cell 110 (of rank No. 108). Moreover, the positive terminal 111 of the cell 110 (of rank No. 108) is connected with and electrically connected to the positive terminal 101 of the battery 100. Likewise, the negative terminal 162 of the cell 160 (of rank No. 1) is connected with and electrically connected to the negative terminal 102 of the battery 100. In order to monitor and to equalize the states of electrical charge of all of the electrical cells 110, 120, 130, 140, 150, 160 of the battery 100, a unit 300 is therefore provided for monitoring those states of charge.

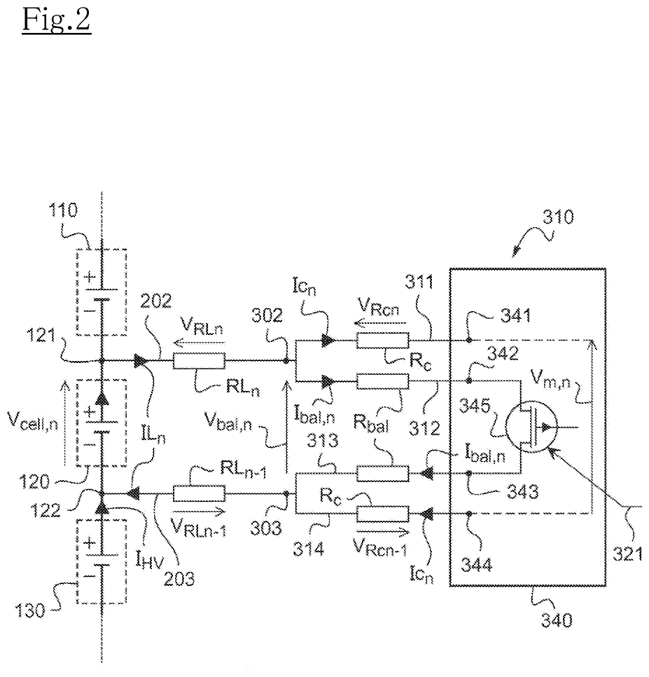

As a general rule, this unit 300 acts as an electronic battery management system (BMS) 100 the principal functions of which are:
to determine the electrical voltages (hereinafter denoted V_{cell,1}, V_{cell,2}, V_{cell,n}, . . . , V_{cell,108}; see FIG. 2 for the voltage V_{cell,n}) at the terminals of the various cells 110, 120, 130, 140, 150, 160 and/or the total voltage U_{BAT} between the positive terminal 101 and the negative terminal 102 of the battery 100;
to determine independently the state of charge (SoC) of each cell 110, 120, 130, 140, 150, 160;
   to determine the total current I_{HV} fed to the electric motor by the battery 100;
   to determine a mean temperature T_{BAT} of the battery 100 or individual temperatures T_{cell,n} (n=1 . . . N) of each of the cells 110, 120, 130, 140, 150, 160 of the battery 100.

The unit 300 also enables balancing of the levels of the electrical capacity of each cell 110, 120, 130, 140, 150, 160. The balancing of the cells 110, 120, 130, 140, 150, 160 may be active or passive.

In the case of active balancing, the monitoring unit takes some of the energy stored in the most charged cell or cells to donate it to the least charged cell or cells. There is therefore a real transfer of actual charge between the various electrical cells.

In the case of passive balancing, the monitoring unit takes some of the energy stored in the most charged cell or cells to dissipate it, generally in the form of heat. In practise, the excess charge of the most charged cells is simply evacuated by the Joule effect in electrical resistances of the unit.

Without this being limiting on the invention, here the situation is that of a unit 300 intended to perform passive balancing of the cells 110, 120, 130, 140, 150, 160 of the battery 100. The remainder of the description will describe in detail the means employed in the unit 300 to perform this balancing of the cells.

In order for the unit 300 to be able to balance the states of electrical charge of the cells 110, 120, 130, 140, 150, 160, each cell 110, 120, 130, 140, 150, 160 of the battery 100 is connected to the unit 300 by an electrical line.

By “cell connected to the unit 300 by an electrical line” is meant, see FIG. 1, that each electrical line may be divided into:
a first electrical branch 201, 202, 203, 204, 205 connecting the positive terminal 111, 121, 131, 151, 161 of the cell 110, 120, 130, 150, 160 concerned to a first input terminal 301, 302, 303, 304, 305 of the unit 300; and
a second electrical branch 202, 203, 204, 205, 206 connecting the negative terminal 112, 122, 142, 152, 162 of the cell 110, 120, 140, 150, 160 concerned to a second input terminal 302, 303, 304, 305, 306 of the unit 300.

In the same way as for the terminals of the cell 110, 120, 130, 140, 150, 160, note that the first electrical branch connecting a cell of rank n to the unit 300 is also the second electrical branch connecting the higher adjacent cell (of rank n+1) to the unit 300.

For example, the first branch 202 of the 107th electrical line that connects the positive terminal 121 of the cell 120 (of rank No.107) to the unit 300 is also the second electrical branch (also referenced 202) of the 108th electrical line that connects the negative terminal 112 (terminal connected with the cell 120) of the cell 110 (of rank No.108). There are therefore as many electrical lines as electrical cells and each electrical line (termed “of rank n” hereinafter) is associated with a particular electrical cell (of rank n).

In other words, two adjacent electrical lines associated with two adjacent cells of adjoining ranks (n and n+1 or n and n−1 for example) having a common (positive or negative) terminal together share a (first or second) electrical branch that connects said common terminal to a (first or second) input terminal of the unit 300.

It will be noted that the “electrical lines” described here are imaginary in the sense that they do not each consist (as FIG. 1 might lead one to believe) of a single electrical wire connecting the positive and negative terminals of a battery cell to two input terminals of the monitoring unit. In fact, here “electrical line” rather means any electrical means enabling circulation and routing of an electrical current between the unit 300 and the cell 110, 120, 130, 140, 150, 160 associated with that line. An electrical line in the sense of the invention is therefore rather an electrical model intended to take into account the existence of cables, wires, connections, connectors, fuses, soldered connections and conductive tracks between a cell 110, 120, 130, 140, 150, 160 and the unit 300. Each electrical line has a state that can evolve over time and affect the results of the measurements carried out by the unit 300 (and therefore also to affect balancing the cells).

According to the invention, that state is evaluated with the aid of a parameter termed the “line resistance” that corresponds overall to the electrical resistance of the electrical line concerned. In order to understand better how the line resistance values may be calculated, there has been shown in FIG. 2 the equivalent electrical circuit diagram under static conditions of the nth electrical cell 120 (here the cell of rank n=107) connected to the unit 300 by the nth electrical line (the line of rank n), which comprises the first electrical branch 202 between the positive terminal 121 of the cell 120 and the input terminal 302 of the unit 300 and the second electrical branch 203 between the negative terminal 122 of the cell 120 and the input terminal 303 of the unit 300.

Under static conditions, the electrical line of rank n is therefore modeled by (see FIG. 2 for the line of rank No. 107):
an equivalent electrical resistance RLₙ of the first branch 202 of said electrical line; and
an equivalent electrical resistance RLₙ₋₁ of the second branch 203 of said electrical line.

As represented in FIG. 1, here the unit 300 includes a microcontroller 330 intended to interact with a printed circuit card 310 by means of two electrical buses:
a first electrical bus 321 extending from the microcontroller 330 to the card 310; and
a second electrical bus 322 extending from the card 310 to the microcontroller 330.

This microcontroller 330 may advantageously be the electronic control unit (i.e. onboard computer) of the motor vehicle and include:
a microprocessor (CPU);
a random access memory (RAM);
a read-only memory (ROM);
analog-digital converters (ADC) or digital-analog converters (DAC); and
various input and output interfaces.

The microprocessor is able to execute various programs stored in the read-only memory. For their part the input interfaces enables the microcontroller 330 to acquire data relating to the electric motor, to the charger and to the cells 110, 120, 130, 140, 150, 160 of the traction battery 100 via the second bus 322, in particular in order to store it in the random access memory. The output interfaces enable the microcontroller 330 to control via the first bus 321 an integrated circuit 340 (see FIG. 2) on the printed circuit card 310.

That integrated circuit 340 is intended to measure the voltages V_{m,n} (see FIG. 2) between:
a first measurement pin 341 of the integrated circuit 340 connected via a load resistor Rc (voltage V_{Rc,n}, current Icₙ) to the first input terminals 302 of the unit 300; and
a second measurement pin 344 of the integrated circuit 340 connected via a load resistor Rc (voltage V_{Rc,n-1}, current Icₙ₋₁) to the second input terminal 303 of the unit 300.

These two measurement pins 341, 344 are therefore associated via load resistors with an electrical line 202, 203 connecting a cell 120 of the battery 100 to the unit 300.

The integrated circuit 340 may for example be an integrated circuit sold by the company Maxim Integrated in the MAX17823 or MAX1785x product range or any other ASSP circuit using the same architecture.

Moreover, the integrated circuit 340 has for each electrical line 202, 203 a transistor 345 (see FIG. 2) that is controlled by the microcontroller 330 via the first bus 321 (see the arrow pointing to the transistor 345 in FIG. 2) and that is connected between a first balancing pin 342 and a second balancing pin 343 and under static conditions has:
a passing state in which it is equivalent to a resistance R_{sw}; and
a blocking state in which it is equivalent to an open circuit (zero current between the two balancing pins).

The microcontroller 330 is also programmed to maintain via the printed circuit card 310 the states of charge of the various cells 110, 120, 130, 140, 150, 160 at the same level in order to prevent any imbalance between the cells 110, 120, 130, 140, 150, 160 that would compromise the service life of the battery 100 and the range of the vehicle.

To this end, the microcontroller 330 controls, as a function of the voltages V_{m,1}, V_{m,2}, . . . , V_{m,n}, . . . , V_{m,N} measured between each each pair of measurement pins, the transistors (e.g. the transistor 345) associated with the electrical lines (e.g. the electrical line formed of the two branches 202, 203) in order:
to place one or more transistors in the blocking state: balancing deactivated (balancing “OFF”) for those transistors;
to place one or more transistors in the passing state: balancing activated (balancing “ON”) for those transistors.

When balancing is activated for a cell 120, i.e. for an electrical line (e.g. for the electrical line 202, 203 in FIG. 2), some of the charge of the cell (here the cell 120 in FIG. 2) is dissipated between the two input terminals 302, 303 of the unit 300 via two electrical balancing resistances R_{bal} (which here are equal but could be different) each placed in a balancing branch 312, 313 between the first input terminal 302 and the first balancing pin 342 and between the second input terminal 303 and the second balancing pin 343.

One objective of the invention is to determine the electrical resistance (in ohms) of each electrical line of the system, hereinafter termed “line resistance” and denoted R_{1,1}, R_{1,2}, . . . , R_{1,n}, . . . , R_{I,N}.

This determination of the line resistances of the electrical lines connecting the cells 110, 120, 130, 140, 150, 160 to the unit 300 may advantageously be used to trigger an alert if the measured value is too high relative to a threshold that can be calibrated.

This determination may also serve to deactivate any faulty diagnostics using the balancing function as part of the monitoring process. Determining the line resistances R_{I,1}, R_{I,2}, R_{I,n}, . . . , R_{I,N} also enables correction of the values V_{cell,1}, V_{cell,2}, . . . , V_{cell,n}, . . . , V_{cell,N} of electrical voltage at the terminals of the cells 110, 120, 130, 140, 150, 160 that are measured by the unit 300 during charging or discharging of one or more cells 110, 120, 130, 140, 150, 160 of the battery 100.

The value of the line resistance may further serve as a reference value at the beginning of the cycle of use of the battery in order to reinitialize the voltage balancing compensation models when that method is used.

In fact, in a nominal cycle of use, if the choice is made to activate balancing at the same time as voltage measurement, the voltage drops along the electrical lines are not negligible, given the accuracy of measuring the voltage at the terminals of the cell, and need to be compensated. To this end, the precise line resistance value of each line must be known in order to reconstruct those voltages.

Each electrical line being formed of two electrical branches 201, 202, 203, 204, 205, 206, the line resistance value R_{I,n} of the electrical line of rank n is equal to the resistance, that is to say: R_{I,n}=R_{Ln}+R_{Ln-1}.

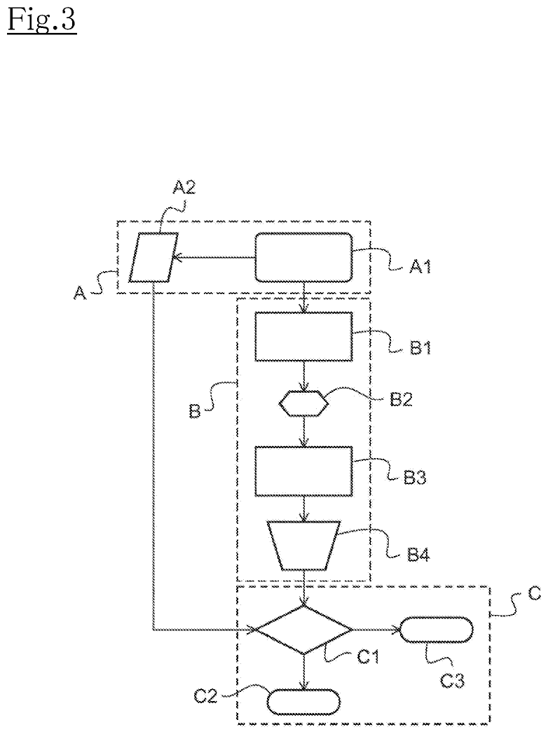

There will now be described with reference to FIG. 3 a determination method enabling correct determination of the line resistance values in question and the state of each electrical line to be deduced therefrom. This method is executed by the unit 300 and to be more precise by the microcontroller 330 of said unit 300. That monitoring unit 300 is therefore designed:
to calculate a line resistance value R_{I,n} of each electrical line 201-202, 202-203, 204-205, 205-206; and
to determine the state of said electrical lines 201-202, 202-203, 204-205, 205-206 as a function of said calculated line resistance values R_{I,n}.

According to the invention, to determine the state of an electrical line said method includes:
a step (block B in FIG. 3) of calculating a line resistance value of said electrical line; and
a step (block C in FIG. 3) of determining the state of said electrical line as a function of that calculated line resistance value.

In order to illustrate the method according to the invention, the remainder of the description will be specific to the determination of the state of the electrical line of rank n (formed by the electrical branches 202 and 203 between the terminals 121 and 302 and between the terminals 122 and 303) as shown in FIG. 2 (line resistance value R_{I,n}=RLₙ+R_{Ln-1}, transistor 345 controlled by the microcontroller 330 of the unit 300).

The method advantageously further includes a step (subblock A1 of the block A in FIG. 3) of measuring the temperatures TL₁, TL₂, . . . , TLₙ, . . . , TL_{N} (hereinafter designated the “line temperature”) representing the temperature around the electrical lines 201-202, 202-203, 204-205, 205-206. In fact, the electrical resistance values in any electrical system are strongly dependent on temperature and it is as well to link the measurement of a line resistance to a surrounding temperature value.

The line temperature values TL₁, TL₂, . . . , TLₙ, . . . , TL_{N} are transferred to and stored in the random access memory of the microcontroller 330 of the unit 300.

If any of the line temperature values TL₁, TL₂, . . . , TLₙ, TL_{N} is below a temperature threshold value TLₘᵢₙ, then in the subsequent calculations it is necessary to take account of the internal resistance of the corresponding cell.

According to a preferred embodiment, the line resistance value R_{I,n} is calculated by carrying out a first measurement without balancing (balancing OFF, transistor 345 in the blocking state: I_{bal,n}=0 A) followed by a second measurement with balancing (balancing ON, transistor 345 in the passing state: I_{bal,n}>0 A) of the electrical voltage V_{bal,n} (see FIG. 2) between each pair of first and second input terminals 302, 303 of the unit 300.

To be more precise, according to this particular embodiment of the determination method according to the invention, the step (block B in FIG. 3) of calculating the line resistance value R_{I,n} comprises:
a first substep (subblock B1) if the cell 120 of the battery 100 is not charging or discharging of measuring a first open circuit voltage value V_{ml,n} between the first input terminal 302 and the second input terminal 303;
a closing substep (subblock B2) at a first time t₁ in which the unit 300 connects the first input terminal 302 and the second input terminal 303 by a resistive electrical branch (formed here by the balancing branches 312, 313 and by the passing branch 342-343 of the transistor 345) the electrical resistance value R_{bal,n} of which is predetermined;
a second substep (subblock B3) of measuring, at a second measuring time t₂ separated from said first measuring time t₁ by a duration Δt between a predetermined minimum duration Vtₘᵢₙ and a predetermined maximum duration Δtₘₐₓ inclusive, a closed circuit second voltage value V_{m2,n} between the first input terminal 302 and the second input terminal 303; and
a substep (subblock B4) of estimating the line resistance value R_{I,n} of that electrical line 202, 203 as a function of said predetermined electrical resistance value R_{bal,n} and the first and second measured voltage values V_{m1,n}, V_{m2,n}.

There will now be described in detail how it is possible in practise to estimate this line resistance value R_{I,n} in the substep B4 on the basis of the measurements of the substeps B1 and B3.

Substep B1

During this first measurement substep it is assumed that static conditions apply and that the power relays of the battery 10 are still open, which guarantees a no-load voltage value U_{BAT} of the battery 10 and an output current IHV equal to 0 ampere. Moreover, during this substep B1, the transistor 345 of the unit 300 is commanded by the microcontroller 330 to be in the blocking mode (balancing OFF), so that the electrical circuit between the two balancing pins 342, 343 is open: I_{bal,n}=0 and Icₙ=ILₙ. It is assumed hereinafter that the input resistance between the two measurement pins 341, 344 is very high, i.e. quasi-infinite relative to the two load resistances Rc of the two measuring branches 311, 314.

Accordingly, when balancing is deactivated (I_{bal,n}=0), the following equation applies: ILₙ=ICₙ=0 A.

In practise, the load resistance values Rc are of the order of 1 to 2 kΩ and Icₙ is less than or equal to 1 μA (set by the integrated circuit 340 and generally around 200 nA) so that the error in measuring the voltage V_{bal,n} owing to the current flowing through the load resistances is negligible compared to the voltage value V_{ml,n} between the two measurement pins 341, 344.

In this way, it is possible to write: V_{cell,n}=V_{bal,n} (because ILₙ≈0 and the internal resistance of the cell is very low) and V_{bal,n}≈V_{m1,n} (because Icₙ=0), whence V_{m1,n}≈V_{cell,n}.

Substep B2

At a first time, hereinafter denoted t₁, the unit 300 triggers the balancing of the cell 120 of rank n (n=107) so that the transistor 345 of the printed circuit 340 goes to the passing state and is equivalent to an electrical resistance of value R_{sw,n} (it may be assumed hereinafter that all the transistors on the printed circuit 340 placed between two balancing terminals are identical and have the same resistance R_{sw}). The electrical resistance value R_{bal,n} of the electrical branch connecting the two input terminals 302, 303 of the unit 300 is then such that: R_{bal,n}=2 R_{bal}+R_{sw}. There follows a wait to the second time t₂ before the next step B3.

Substep B3

The second time t₂ is chosen so that the time interval Δt=t₂−t₁ between the first time t₁ and the second time t₂ is between a predetermined minimum interval Δtₘᵢₙ and a predetermined maximum interval Δtₘₐₓ inclusive, preferably such that:
the second measurement substep B3 is carried out under static electrical conditions: t₂ sufficiently far from t₁ for static conditions to apply; and
the absolute value V_{cell,n} of the voltage between the positive and negative terminals 121, 122 of the cell 120 does not vary by more than 1% between the first and second measurement substeps B1, B3: t₂ not too far from t₁ to be able to ignore (to within 1%) the voltage variation at the terminals of the cell 120.

In practise, static conditions are achieved after a few tens of milliseconds, that is to say Δtₘᵢₙ=10 to 50 ms; and the value V_{cell,n} of the cell voltage begins to fall only after a few minutes, that is to say Δtₘₐₓ=from 1 to 3 minutes. Once the transistor 345 is in the passing mode and static conditions have been established, the voltage V_{m2,n} between the two measurement pins 341, 344 of the integrated circuit 340 is measured at the same time t₂.

Substep B4

Following the two measurement substeps B1 and B3, there are known the values V_{m1,n} and V_{m2,n} between the two measurement pins 341, 344 of the integrated circuit 340 when balancing is deactivated (I_{bal,n}=0 A) and when it is activated (I_{bal,n}>0 A). These two values are transmitted via the second bus 322 from the unit 300 to the microcontroller 330 that will use them to calculate the line resistance value R_{I,n}.

The following equations apply to the electrical voltage values in FIG. 2:

V_{cell,n}=V_{bal,n}+V_{RLn}−V_{RLn-1}=V_{bal,n}+(RLₙ+RLₙ₋₁)*ILₙ=V_{bal,n}+R_{I,n}*ILn (a)

V_{m2,n}≈V_{bal,n} (b)

V_{bal,n}=R_{bal,n}*I_{bal,n}=(2*R_{bal}+R_{sw,n})*I_{Ln} (c)

Combining the above three equations (a), (b) and (c) with the equation V_{m1,n}=V_{cell,n} (see substep B1 above) there is then obtained R_{I,n}=(V_{m1,n}−V_{m2,n})/ILₙ, that is to say: R_{I,n}=(2*R_{bal}+R_{sw,n})*[(V_{m1,n}/V_{m2,n})−1].

The microcontroller 330 uses the above formula to estimate the line resistance. The microprocessor of the microcontroller 330 is programmed to perform the calculation in accordance with the above formula for all the electrical lines.

The microcontroller 300 is advantageously programmed to control in a first phase only the transistors of the integrated circuit 340 associated with an electrical line of odd rank to calculate the line resistance of those lines of odd rank, the transistors associated with the electrical lines of even rank being maintained in the blocking state. This enables uncoupled measurements on the cells of odd rank and the cells of even rank.

Thus, in this first phase only the values R_{I,n} (with n=2* k+1, k=0, 1, 2, . . . , Ent(N/2)−1) of the line resistances of the electrical lines of odd rank are calculated.

The microcontroller 330 is programmed to control in a second phase the transistors of the integrated circuit 340 associated with the electrical lines of even rank to calculate the line resistance values of those lines of even rank.

Following the calculation step B, the unit 300 holds in the random access memory of the microcontroller 330:
the values TL₁, TL₂, . . . , TLₙ, . . . , TL_{N} of the representative temperature of each electrical line; and
the values R_{I,1}, R_{I,2}, . . . , R_{I,n}, . . . , R_{I,N} of the line resistance of each electrical line.

During the determination step C (see FIG. 3) the state of each electrical line is determined as a function of the values R_{I,1}, R_{I,2}, . . . , R_{I,n}, . . . , R_{I,N} of the line resistance of each electrical line.

In a preferred embodiment, the determination step C includes a comparison substep (subblock C1 in FIG. 3) in which the unit 300 and to be more precise the microprocessor of the microcontroller 330 compares the electrical resistance value R_{I,n} of each electrical line with a predetermined electrical resistance threshold value RLₘₐₓ. The electrical resistance threshold value RL_{max,n} of the electrical line of rank n is preferably predetermined (subblock A2 of the block A in FIG. 1) as a function of the representative temperature TLₙ of that electrical line. If the foregoing comparison shows that the line resistance value R_{I,n} of the electrical line of rank n is lower than the threshold value RL_{max,n} (subblock C2 in FIG. 3), then the unit 300 considers that the electrical line of rank n is in a normal operating state.

Conversely, if the foregoing comparison shows that the line resistance value R_{I,n} of the electrical line of rank n is greater than the threshold value RL_{max,n} (subblock C3 in FIG. 3), then the unit 300 considers that the electrical line of rank n is in an abnormal operating state and that a line impedance fault has been detected on that electrical line of rank n.

In this case, the unit 300 may control the integrated circuit 340 in such a manner as to deactivate the diagnostic functions impacted by the change in the line resistance value of the faulty electrical line. An alert signal may also be sent if the line resistance value R_{I,n} is greater than said electrical resistance threshold value RL_{max,n} for the temperature TLₙ concerned.

The present invention is in no way limited to the embodiment described and shown and the person skilled in the art will know how to arrive at any variant thereof within the spirit thereof.

1. A method for determining the state of an electrical line connecting a cell of a battery to a monitoring unit of said battery, said electrical line including a first electrical branch connecting a positive terminal of said cell to a first input terminal of said monitoring unit and a second electrical branch connecting a negative terminal of said cell to a second input terminal of said monitoring unit, said method including:
calculating a value of the line resistance of said electrical line; and
determining the state of said electrical line as a function of said calculated line resistance value.

2. The method as claimed in claim 1, in which said calculating the line resistance value includes:
a first measurement substep, when said cell of said battery is not charging or discharging, of measuring an open circuit first voltage value between said first and second input terminals;
a closing substep, at a first time, in which the monitoring unit connects said first and second input terminals via a resistive electrical branch the electrical resistance value of which is predetermined;
a second measurement substep, at a second separated from said first time by a duration between a predetermined minimum duration and a predetermined maximum duration, of measuring a closed circuit second voltage value between said first and second input terminals; and
a substep of estimating said line resistance value of said electrical line as a function of said predetermined electrical resistance value and said first and second measured voltage values.

3. The method as claimed in claim 2, in which:
said minimum duration is predetermined so that said second measurement substep is carried out under static electrical conditions; and
said maximum duration is predetermined so that the absolute value of the voltage between said positive and negative terminals of said cell does not vary by more than 1% between the first measurement substep and the second measurement substep.

4. The method as claimed in claim 2, in which, during the closing substep, each resistive electrical branch is a balancing electrical branch of a cell.

5. The method as claimed in claim 1, further including comparing the calculated line resistance value with an electrical resistance threshold value and in which the state of said electrical line is determined as a function of the result of said comparison.

6. The method as claimed in claim 5, further including measuring a temperature representative of the ambient temperature of said electrical line and in which said electrical resistance threshold value is predetermined as a function of that representative temperature.

7. A method of issuing an alert regarding the state of an electrical line connecting a cell of a battery to a monitoring unit of said battery, said electrical line including a first electrical branch connecting a positive terminal of said cell to a first input terminal of said monitoring unit and a second electrical branch connecting a negative terminal of said cell to a second input terminal of said monitoring unit, said method of issuing an alert including:
determining the state of said electrical line using a determination method as claimed in claim 5; and
sending an alert signal if the line resistance value is greater than said electrical resistance threshold value.

8. A unit for monitoring states of charge of a plurality of cells of a battery, each cell being connected to said monitoring unit by an electrical line including a first electrical branch connecting a positive terminal of said cell to a first input terminal of said monitoring unit and a second electrical branch connecting a negative terminal of said cell to a second input terminal of said monitoring unit, said monitoring unit being designed:
to calculate a line resistance value of each electrical line;
to determine the state of said electrical lines as a function of said calculated line resistance values.

9. A system for electric or hybrid motor vehicles, including:
a battery comprising a plurality of cells; and
a monitoring unit according to claim 8 for said battery.

10. An electric or hybrid motor vehicle including:
a system according to claim 9; and
an electric motor supplied with current by said battery of said system.
